(19) United States
(12) Patent Application Publication
(10) Pub. No.: US 2025/0040415 A1
(43) Pub. Date: Jan. 30, 2025

(54) DRIVING CIRCUIT, DRIVING METHOD, AND DISPLAY DEVICE

(71) Applicant: HKC CORPORATION LIMITED, Shenzhen (CN)

(72) Inventors: Jing LI, Shenzhen (CN); Haijiang YUAN, Shenzhen (CN)

(21) Appl. No.: 18/743,144

(22) Filed: Jun. 14, 2024

(30) Foreign Application Priority Data
Jul. 28, 2023 (CN) 202310948065.8

(51) Int. Cl. H10K 59/80; H10K 59/122

(52) U.S. Cl. CPC H10K 59/8791; H10K 59/122

(57) ABSTRACT

A display panel is disclosed and includes a substrate, a light-emitting element layer, a pixel defining layer, an encapsulation layer, a color filter layer, and an anti-reflection layer. The light-emitting element layer includes multiple light-emitting elements. The pixel defining layer is disposed on the substrate and in the non-opening region. Every two adjacent light-emitting elements are separated by the pixel defining layer. The encapsulation layer is disposed on the light emitting units and the pixel defining layer. The color filter layer includes multiple color filters arranged on the encapsulation layer and located in the opening region. The anti-reflection layer is disposed corresponding to the pixel defining layer and located in the non-opening region to block external light from entering the display panel. The anti-reflection layer includes an alignment film and polarizing molecules evenly distributed within the alignment film. The polarizing molecules are mutually perpendicularly aligned in the alignment film.

### CROSS-REFERENCE TO RELATED APPLICATIONS

This application claims the priority and benefit of Chinese patent application number 2023109480658, titled “Driving Circuit, Driving Method, and Display Device” and filed Jul. 28, 2023 with China National Intellectual Property Administration, the entire contents of which are incorporated herein by reference.

### TECHNICAL FIELD

This application relates to the field of display technology, and in particular, to a display panel and a display device.

### BACKGROUND

The description provided in this section is intended for the mere purpose of providing background information related to the present application but doesn't necessarily constitute prior art.

With the continuous development of OLED (Organic Light-Emitting Diode) display technology, OLED is increasingly used in displays such as smartphones, tablets, computers, and TVs. OLED displays have the advantages of thinness and light weight, high contrast, fast response, wide viewing angle, high brightness, and full-color, etc. In order to reduce the reflectivity of external light in an OLED display, the current mainstream solution is to attach a circular polarizer to a light-emitting surface of the OLED display. However, this solution reduces the light-emitting effect due to the relatively great light loss of the circular polarizer. Another solution is to dispose a color filter on the light-emitting surface of the OLED display, also known as a COE (Color filter on Encapsulation) display panel, to improve the light-emitting efficiency through the color filter.

However, due to the structure of the COE display panel, the ambient reflected light is stronger than that of the display panel equipped with a polarizer, which easily causes problems such as glare. In this regard, those having ordinary skill in the art are in urgently need of a technical solution that can solve the problem of ambient light reflection.

### SUMMARY

In view of the above, it is one purpose of this application to provide a display panel and a display device to improve the phenomenon of ambient light reflection without affecting the light emitting efficiency.

This application discloses a display panel, which includes an opening region and a non-opening region. The display panel includes a substrate, a light-emitting element layer, a pixel defining layer, an encapsulation layer, a color filter layer, and an anti-reflection layer. The light-emitting element layer includes a plurality of light-emitting elements. The plurality of light emitting units are arranged in an array on the substrate and located in the opening region. The pixel defining layer is disposed on the substrate and located in the non-opening region. Every two adjacent light-emitting elements are separated by the pixel defining layer. The encapsulation layer is disposed on the light emitting units and the pixel defining layer. The color filter layer includes a plurality of color filters, which are arranged on the encapsulation layer and located in the opening region. The anti-reflection layer is disposed corresponding to the pixel defining layer and is located in the non-opening region to block external light from entering the display panel. The anti-reflection layer includes an alignment film and polarizing molecules evenly distributed within the alignment film. The polarizing molecules are mutually perpendicularly aligned in the alignment film.

In some embodiments, the light-emitting element includes a top electrode, a light-emitting layer, and a bottom electrode. The bottom electrode, the light-emitting layer, and the top electrode are sequentially stacked on the substrate. The bottom electrode is disposed under the pixel defining layer. The anti-reflection layer includes a first anti-reflection layer disposed between the pixel defining layer and the bottom electrode.

In some embodiments, the orthographic projection of the first anti-reflection layer on the substrate partially overlaps the orthographic projection of the bottom electrode on the substrate, and they have a first overlapping width. The orthographic projection of the bottom electrode on the substrate partially overlaps the orthographic projection of the pixel defining layer on the substrate, and they have a second overlapping width. The first overlapping width is less than or equal to the second overlapping width.

In some embodiments, the light-emitting element includes a top electrode, a light-emitting layer, and a bottom electrode. The bottom electrode, the light-emitting layer, and the top electrode are sequentially stacked on the substrate. The bottom electrode is disposed under the pixel defining layer. The anti-reflection layer includes a second anti-reflection layer disposed between the pixel defining layer and the encapsulation layer.

In some embodiments, there is defined a groove in the pixel defining layer, and the second anti-reflection layer is disposed in the groove.

In some embodiments, the orthographic projection of the second anti-reflection layer on the substrate partially overlaps the orthographic projection of the bottom electrode on the substrate.

In some embodiments, the display panel further includes a local light-transmitting layer. A partial area of the light-transmitting layer is used to block external light from entering the display panel. The local light-transmitting layer is arranged on the encapsulation layer. The local light-transmitting layer includes a light-shielding piece and a light-transmitting piece. The light-shielding piece is arranged corresponding to the non-opening region. The light-transmitting piece is arranged corresponding to the opening region. The polarizing molecules of the light-shielding piece are arranged in mutually perpendicular orientations in the alignment film. There are no polarizing molecules in the light-transmitting piece.

In some embodiments, the local light-transmitting layer further includes a semi-shielding piece, and the polarizing molecules in the semi-shielding piece are arranged in a unidirectional orientation within the alignment film. The semi-shielding piece is arranged between the light-shielding piece and the light-transmitting piece. The semi-shielding piece extends from the opening region to the non-opening region. The area of the semi-shielding piece is smaller than the area of the light-shielding piece and smaller than the area of the light-transmitting piece.

In some embodiments, the local light-transmitting layer further includes a semi-shielding piece, and the polarizing molecules in the semi-shielding piece are arranged in a unidirectional orientation within the alignment film. The plurality of light-emitting elements include a plurality of white light-emitting elements and a plurality of first light-emitting elements. The orthographic projection of the semi-shielding piece on the substrate overlaps the orthographic projection of the white light-emitting element on the substrate. The plurality of color filters are arranged in one-to-one correspondence with The plurality of first light-emitting elements. The plurality of first light-emitting elements include at least two light-emitting elements with different colors.

This application further discloses a display device, including a driving circuit and the above-mentioned display panel, wherein the driving circuit is used to drive the display panel to display.

In this application, the alignment film is used and the polarizing molecules are arranged in the alignment film, and the polarizing molecules are arranged in an oriented manner to absorb the incident light from the outside world and prevent external incident light from entering the display panel and causing some of the film layers in the display panel to reflect the incident light, causing problems such as glare. In this application, the anti-reflection layer is arranged corresponding to the pixel defining layer so that the pixel defining layer is shielded from light by the anti-reflection layer. Compared with the scheme of blackening the pixel defining layer or disposing a black color filter on the pixel defining layer for light-shielding, carbon black may be used to blacken the pixel defining layer, which causes the insulation of the pixel defining layer to be weakened. If a black color filter is disposed on the pixel defining layer, the black color filter material will easily cause erosion and defects on the pixel defining layer. In this application, by arranging the alignment film on the pixel defining layer, no interface characteristics may occur between the alignment film and the pixel defining layer, and the manufacturing process of the alignment film is mature. Thus, the anti-reflection layer is used to improve the phenomenon of ambient light reflection without reducing the brightness and display effect. The anti-reflection layer of the present application is formed by an alignment film and polarizing molecules, and has a simple structure, simple manufacturing process, and low cost.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principle of the present application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic diagram of a display panel according to a first embodiment of the present application.

FIG. 2 is a schematic diagram of an anti-reflection layer of the present application.

FIG. 3 is a schematic diagram of a display panel according to a second embodiment of the present application.

FIG. 4 is a schematic diagram of another display panel according to the second embodiment of the present application.

FIG. 5 is a schematic diagram of yet another display panel according to the second embodiment of the present application.

FIG. 6 is a schematic diagram of a display panel according to a third embodiment of the present application.

FIG. 7 is a schematic diagram of a semi-shielding piece of a local light-transmitting layer of the present application.

FIG. 8 is a schematic diagram of another display panel according to the third embodiment of the present application.

FIG. 9 is a schematic diagram of yet another display panel according to a third embodiment of the present application.

FIG. 10 is a schematic diagram of a display device according to a fourth embodiment of the present application.

In the drawings: 100, display panel; 101, opening region; 102, non-opening region; 110, substrate; 120, light-emitting element layer; 121, light-emitting element; 122, first light-emitting element; WLED, white light-emitting element; 123, bottom electrode; 124, light-emitting layer; 125, top electrode; 130, pixel defining layer; 131, groove; 140, encapsulation layer; 150, color filter layer; 151, color filter; R, red filter; G, green filter; B, blue filter; 160, anti-reflection layer; 161, alignment film; 162, polarizing molecules; 163, first anti-reflection layer; 164, second anti-reflection layer; 165, local light-transmitting layer; 166, light-shielding piece; 167, semi-shielding piece; 168, light-transmitting piece; 170, thin film transistor layer; 200, display device; 210, driving circuit.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

Hereinafter this application will be described in further detail with reference to the accompanying drawings and some optional embodiments.

### Embodiment 1

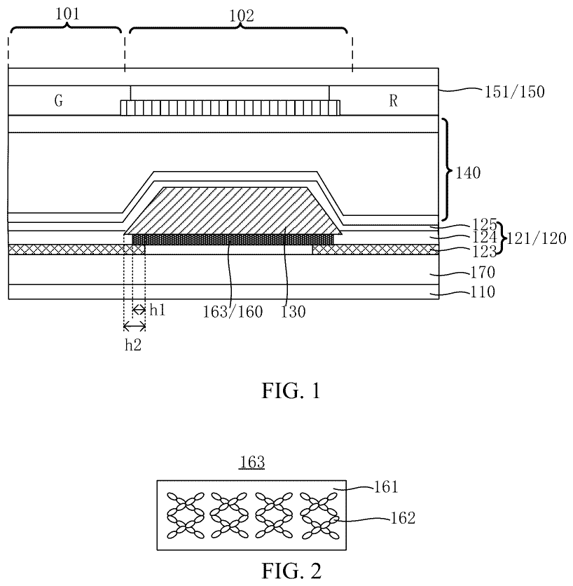

FIG. 1 is a schematic diagram of a display panel according to a first embodiment of the present application. As shown in FIG. 1, the display panel 100 includes a substrate 110, a light-emitting element layer 120, a pixel defining layer 130, an encapsulation layer 140, a color filter layer 150, and an anti-reflection layer 160. The light-emitting element layer 120 includes a plurality of light-emitting elements 121. The plurality of light emitting units 121 are arranged in an array on the substrate 110 and located in the opening region 101. The pixel defining layer 130 is disposed on the substrate 110 and located in the non-opening region 102. Every two adjacent light-emitting elements 121 are separated by the pixel defining layer 130. The encapsulation layer 140 is disposed on the light emitting units 121 and the pixel defining layer 130. The color filter layer 150 includes a plurality of color filters 151, which are disposed on the encapsulation layer 140 and located in the opening region 101. The anti-reflection layer 160 is disposed corresponding to the pixel defining layer 130 and is located in the non-opening region 102 to block external light from entering the display panel 100. The anti-reflection layer 160 includes an alignment film 161 and polarizing molecules 162 evenly distributed in the alignment film 161. The polarizing molecules 162 are aligned to be mutually perpendicular to each other in the alignment film 161.

This application uses the alignment film 161 and the polarizing molecules 162 disposed in the alignment film 161 to achieve the absorption of incident light from the outside by orienting the polarizing molecules 162, thus preventing external incident light from entering the display panel 100 which may cause some of the film layers in the display panel 100 to reflect the incident light hence leading to problems such as glare. In this application, the anti-reflection layer 160 is arranged corresponding to the pixel defining layer 130 so that the pixel defining layer 130 is shielded from light by the anti-reflection layer 160. Compared with the scheme of blackening the pixel defining layer 130 or disposing a black color filter on the pixel defining layer 130 for light-shielding, carbon black may be used to blacken the pixel defining layer 130, which causes the insulation of the pixel defining layer 130 to be weakened. If a black color filter is disposed on the pixel defining layer 130, the black color filter material will easily cause erosion and defects on the pixel defining layer 130. In this application, by arranging the alignment film 161 on the pixel defining layer 130, no interface characteristics may occur between the alignment film 161 and the pixel defining layer 130, and the manufacturing process of the alignment film 161 is mature. Thus, the anti-reflection layer 160 is used to improve the phenomenon of ambient light reflection without reducing the brightness and display effect. The anti-reflection layer 160 of the present application is formed by an alignment film 161 and polarizing molecules 162, and has a simple structure, simple manufacturing process, and low cost.

It may be understood that in this embodiment, the polarizing molecules 162 are molecules with polarizing effects, such as iodine dye molecules, which have light-absorbing properties when aligned. The alignment film 161 is made of a resin material and has a transparent state. This application creates light absorption characteristics by orderly arranging the polarizing molecules 162 in the alignment film 161.

FIG. 2 is a schematic diagram of an anti-reflection layer of the present application. As shown in FIG. 2, the an-ti-reflective layer 160 at least includes an opaque state. When the polarizing molecules 162 of the anti-reflection layer 160 have a bidirectional arrangement, they may be mutually perpendicularly arranged. At this time, when the polarizing molecules 162 in the alignment film 161 are arranged in two directions and are arranged perpendicularly, they are similar to two polarizing layers with perpendicular absorption axes, and thus have a superior light-shielding effect. The shading effect can reach more than 99.95%. The bidirectionally perpendicularly arranged polarizing molecules 162 form mutually perpendicular alignments through alignment forces in two perpendicular directions, based on illumination with an alignment direction of a and illumination of a+90°. This a is perpendicular to the normal direction of the display panel 100.

In this embodiment, the light-emitting elements 121 emit light after passing through each color filter 151. Each light-emitting element 121 is controlled by a corresponding thin film transistor to achieve controllable brightness of each sub-pixel. Specifically, a thin film transistor layer 170 is disposed below the light-emitting element layer 120 and the pixel defining layer 130, and each light-emitting element 121 is separately controlled by providing an array of thin film transistors.

The anti-reflection layer 160 in this embodiment is mainly used to block ambient light from entering the thin film transistor layer 170 from the pixel defining layer 130 and prevent the metal layer in the thin film transistor layer 170 from reflecting the ambient light out, causing light reflection problems.

Specifically, the light-emitting element 121 includes a top electrode 125, a light-emitting layer 124, and a bottom electrode 123. The bottom electrode 123, the light-emitting layer 124, and the top electrode 125 are sequentially stacked on the substrate 110. The bottom electrode 123 is disposed under the pixel defining layer 130. The bottom electrode 123 may use a metal electrode as the anode of the light-emitting element 121. Of course, there is also a composite electrode using a stack of a transparent conductive layer and a metal electrode as the anode. The top electrode 125 may use a transparent conductive layer as the cathode of the light-emitting element 121. Since the bottom electrode 123 has high reflective properties, when driven by a certain voltage, electrons and holes move from the cathode and anode to the light-emitting layer 124 respectively and recombine to emit visible light. Therefore, the light-emitting element 121 may emit light in one direction, such as a bottom-emitting light-emitting element 121. There is also a top-emitting light-emitting element 121, which switch the anode and cathode materials to form light emitted from top to bottom.

The light-emitting element 121 in this embodiment includes a red light-emitting element 121, a green light-emitting element 121, and a blue light-emitting element 121. The red light-emitting element 121, the green light-emitting element 121, and the blue light-emitting element 121 are arranged in an array. The effective light-emitting area of the light-emitting element 121 is the anode disposed between the pixel defining layers 130, which emits light by exciting the light-emitting layer 124. The area where the anode is blocked by the pixel defining layer 130 does not actually emit light. The display panel 100 in this embodiment is an OLED display panel 100 using the RGB light-emitting elements 121 as the light sources. Of course, the light-emitting elements 121 in this application may also be a white light-emitting element WLED to form the OLED display panel 100 using white light as the light source.

The color filters 151 include a red filter R, a green filter G, and a blue filter B. When the light-emitting elements 121 of the display panel 100 are RGB light-emitting elements 121, the red filter R is disposed corresponding to the red light-emitting element 121, the green filter G is disposed corresponding to the green light-emitting element 121, and the blue filter B is disposed corresponding to the blue light-emitting element 121. When the display panel 100 uses white light-emitting elements (WLEDs), then the red filters R, the green filters G, and the blue filters B are arranged in an array.

In this embodiment, the anti-reflection layer 160 is disposed corresponding to the pixel defining layer 130. In a specific embodiment, the anti-reflection layer 160 includes a first anti-reflection layer 163. The first anti-reflection layer 163 is disposed between the pixel defining layer 130 and the bottom electrode 123.

In this embodiment, the first anti-reflection layer 163 is disposed below the pixel defining layer 130. At a previous manufacturing proce-dure prior to forming the pixel defining layer 130, the polarizing mole-cules 162 may be formed and doped internally, and the polarizing mole-cules 162 may then be solidified through bidirectional perpendicular alignment to form bidirectionally perpendicularly aligned polarizing molecules 162. The first anti-reflection layer 163 has a light-shielding rate of more than 99.95%, thus achieving a light-shielding effect on the pixel defining layer 130.

Specifically, the orthographic projection of the first anti-reflection layer 163 on the substrate 110 partially overlaps the orthographic pro-jection of the bottom electrode 123 on the substrate 110, and they have a first overlapping width h1. The orthographic projection of the bottom electrode 123 on the substrate 110 partially overlaps the orthographic projection of the pixel defining layer 130 on the substrate 110 and they have a second overlapping width h2. The first overlapping width h1 is less than or equal to the second overlapping width h2.

It may be understood that the anode of the light-emitting element 121 may extend from the opening region 101 to the non-opening region 102, and an anode is also formed below the pixel defining layer 130. Therefore, the anode and the pixel defining layer 130 form a first over-lapping width in the overlapping area. Since the pixel defining layer 130 is in a transparent state, the anode below the pixel defining layer 130 does not emit light but reflects ambient light. In this regard, in this embodiment, the first anti-reflection layer 163 is disposed to cover the anode under the pixel defining layer 130 to prevent the anode part from reflecting light.

In this embodiment, considering that the thickness of the anode itself is relatively thin, so when the first anti-reflection layer 163 is disposed below the pixel defining layer 130, it will not cause the flatness problem of the film layers. Furthermore, the first anti-reflection layer 163 does not extend into the effective light-emitting area of the anode, so it does not affect the hole transmission of the anode to the light-emitting layer 124 and does not affect the effective light-emitting area of the light-emitting element 121.

### Embodiment 2

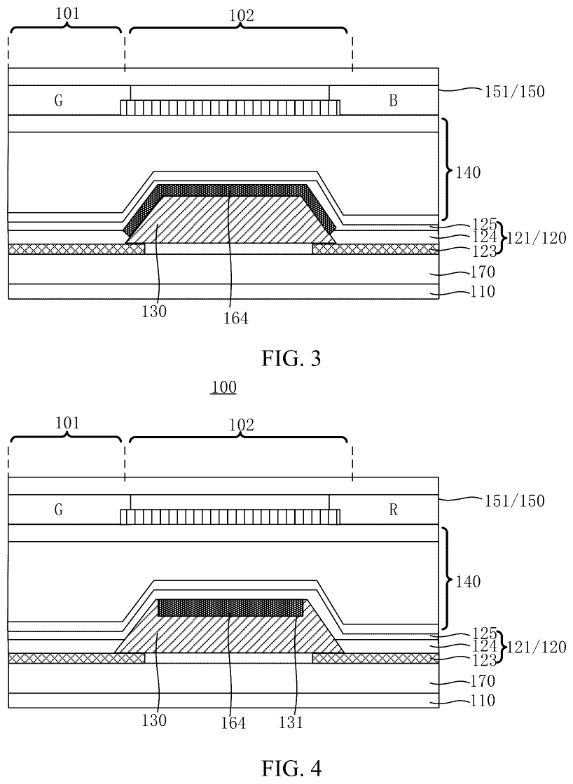

FIG. 3 is a schematic diagram of a display panel according to a second embodiment of the present application. As shown in FIG. 3, the display panel 100 includes a substrate 110, a light-emitting element layer 120, a pixel defining layer 130, an encapsulation layer 140, a color filter layer 150, and an anti-reflection layer 160. The light-emitting element layer 120 includes a plurality of light-emitting elements 121. The plurality of light emitting units 121 are arranged in an array on the substrate 110 and located in the opening region 101. The pixel defining layer 130 is disposed on the substrate 110 and located in the non-opening region 102. Every two adjacent light-emitting elements 121 are separated by the pixel defining layer 130. The encapsulation layer 140 is disposed on the light emitting units 121 and the pixel defining layer 130. The color filter layer 150 includes a plurality of color filters 151, which are disposed on the encapsulation layer 140 and located in the opening region 101. The anti-reflection layer 160 is disposed corresponding to the pixel defining layer 130 and is located in the non-opening region 102 to block external light from entering the display panel 100. The anti-reflection layer 160 includes an alignment film 161 and polarizing molecules 162 evenly distributed in the alignment film 161. The polarizing molecules 162 are mutually perpendicularly aligned in the alignment film 161.

The anti-reflection layer 160 includes a second anti-reflection layer 164. The second anti-reflection layer 164 is disposed between the pixel defining layer 130 and the encapsulation layer 140.

In this embodiment, the second anti-reflection layer 164 is disposed above the pixel defining layer 130. After the forming process of the pixel defining layer 130 is completed, a layer of alignment film 161 with polarizing molecules 162 is coated on the upper surface of the pixel defining layer 130. The process of forming the alignment film 161 on the pixel defining layer 130 may be accomplished using a coating or inkjet process. Through mutually perpendicular UV irradiations, the polarizing molecules 162 are bidirectionally perpendicularly arranged in the alignment film 161 to achieve a light-shielding effect.

Specifically, the second anti-reflection layer 164 also covers the sides of the pixel defining layer 130; more particularly, it extends from one side of the pixel defining layer 130 to the top surface, and then covers the other side of the pixel defining layer 130. However, the orthographic projection of the second anti-reflection layer 164 on the substrate 110 does not overlap the effective light-emitting area of the anode, that is, it does not affect the effective light-emitting area of the light-emitting element 121.

In this application, the second anti-reflection layer 164 is disposed above the pixel defining layer 130, completely covering the top and side surfaces of the pixel defining layer 130, and then the top electrode 125 of the light-emitting element 121 is subsequently formed on the pixel defining layer 130, covering the second anti-reflection layer 164.

In this embodiment, a black matrix is further disposed in the color filter layer 150. The black matrix is disposed corresponding to the non-opening region 102 and corresponding to the pixel defining layer 130. The arrangement of the black matrix can reduce most of the incident light, but there is still light at a large angle that is incident from the color filter 151 and enters the thin film transistor layer 170 and the anode from the side or top surfaces of the pixel defining layer 130, easily causing problems such as ambient light reflection. However, this embodiment greatly improves the phenomenon by covering the side and top surfaces of the pixel defining layer 130 with the second anti-reflection layer 164. It is worth mentioning that the alignment film 161 may be formed on the sides of the pixel defining layer 130 through a coating or inkjet process.

FIG. 4 is a schematic diagram of another display panel according to the second embodiment of the present application. Referring to FIG. 4, in another modified embodiment, a groove 131 may be defined in the pixel defining layer 130, and the second anti-reflection layer 164 may be disposed in the groove 131. In this embodiment, it is considered that even if the thickness of the second anti-reflection layer 164 is thin, it may be about 100 μm to the thinnest. However, relatively speaking, it may still cause the problem of film layer discontinuity, and the subsequent formation of the top electrode 125 made of transparent conductive layer material may easily cause the problem of disconnection.

In this embodiment, the groove 131 is defined in the pixel defining layer 130, and the second anti-reflection layer 164 is disposed in the groove 131. This results in a relatively greater flatness on the pixel defining layer 130 and makes it less likely to break when forming the top electrode 125 of the light emitting unit 121.

It can be understood that since the second anti-reflection layer 164 is farther away from the underlying thin film transistor layer 170, the orthographic projection of the second anti-reflection layer 164 on the substrate 110 needs to at least partially overlap the orthographic projection of the bottom electrode 123 on the substrate 110. Similarly, the overlapping width cannot exceed the overlapping width of the bottom electrode 123 and the pixel defining layer 130.

FIG. 5 is a schematic diagram of yet another display panel ac-cording to the second embodiment of the present application. As shown in FIG. 5, the second anti-reflection layer 164 in this embodiment is used in conjunction with the first anti-reflection layer 163 in the previous embodiment to form a double-layer structure.

### Embodiment 3

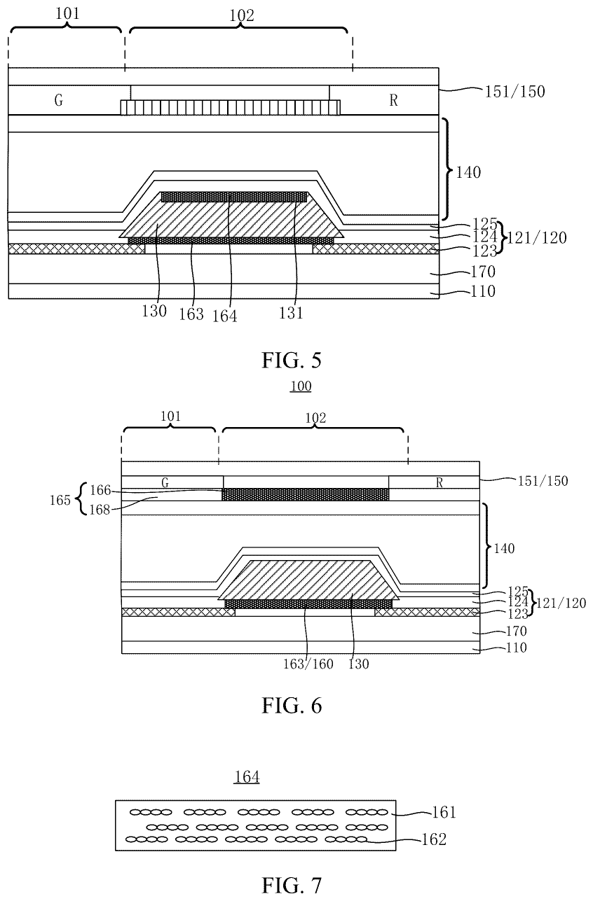

FIG. 6 is a schematic diagram of a display panel according to a third embodiment of the present application. As shown in FIG. 6, the display panel 100 includes a substrate 110, a light-emitting element layer 120, a pixel defining layer 130, an encapsulation layer 140, a color filter layer 150, and an anti-reflection layer 160. The anti-reflection layer 160 is disposed corresponding to the pixel defining layer 130 and is located in the non-opening region 102 to block external light from entering the display panel 100. The anti-reflection layer 160 includes an alignment film 161 and polarizing molecules 162 evenly distributed in the alignment film 161. The polarizing molecules 162 are arranged in mutually perpendicular orientations in the alignment film 161.

The display panel 100 further includes a local light-transmitting layer 165. Part of the local light-transmitting layer 165 is used to block external light from entering the display panel 100. The local light-transmitting layer 165 is disposed on the encapsulation layer 140. The local light-transmitting layer 165 includes a light-shielding piece 166, a semi-shielding piece 167, and a light-transmitting piece 168. The light-shielding piece 166 is disposed corresponding to the non-opening region 102. The light-transmitting piece 168 is disposed corresponding to the opening region 101. The semi-shielding piece 167 is disposed corresponding to the opening region 101. The polarizing molecules 162 of the light-shielding piece 166 are mutually perpendicularly aligned in the alignment film 161. The polarizing molecules 162 of the semi-shielding piece 167 are arranged in a unidirectional orientation in the alignment film 161. There are no polarizing molecules 162 disposed in the light-transmitting piece 168. It is worth mentioning that the local light-transmitting layer 165 in the third embodiment may be used in combination with the first anti-reflection layer 163 and the second anti-reflection layer 163 in the display panel 100 in any of the first and second embodiments.

In this application, the local light-transmitting layer 165 may be disposed in a local area at the position of the color filter layer 150, and the polarizing molecules 162 in the light-shielding piece 166 may all be arranged in two mutually perpendicular orientations to replace the black matrix in the display panel 100. The local light-transmitting layer 165 is used to improve the phenomenon of ambient light reflection without reducing the brightness and display effect.

The local light-transmitting layer 165 at least includes three states: opaque, transparent, and semi-transparent. For the opaque state, refer to the description in the first embodiment above and it will not be described again here. However, no alignment film 161 and polarizing molecules 162 are disposed at the location of the light-transmitting piece 168. It can be understood that in this embodiment, the semi-shielding piece 167 does not need to be used. The black matrix is replaced by disposing the light-shielding piece 166 between adjacent color filters 151.

FIG. 7 is a schematic diagram of a semi-shielding piece of a local light-transmitting layer of the present application. As shown in FIG. 7, when the polarizing molecules 162 in the anti-reflection layer 160 are aligned in one same orientation, the polarizing molecules 162 in the alignment film 161 are aligned in a single orientation and have a semi-transparent state. When arranged in one direction, the polarizing molecules 162 are similar to slits in a polarizer, forming a polarizing effect that prevents part of the ambient light from entering, thereby reducing reflection. In a specific process, the alignment film 161 can be illuminated in one direction, so that the alignment film 161 has an alignment force in one direction, thereby forming unidirectionally arranged polarizing molecules 162. Specifically, the alignment force only needs to be perpendicular to a normal direction of the display panel 100.

Specifically, the concentration of polarizing molecules 162 in the alignment film 161 is no more than 20%. In this application, the light-shielding or semi-transmitting effect is mainly achieved through the directional arrangement of the polarizing molecules 162, and it is not necessary for the polarizing molecules 162 to completely fill the alignment film 161. By adjusting the arrangement of the polarizing molecules 162, the semi-transparent and opaque states are achieved.

In this embodiment, the light-emitting elements 121 emit light after passing through each color filter 151. Each light-emitting element 121 is controlled by a corresponding thin film transistor to achieve controllable brightness of each sub-pixel. Specifically, a thin film transistor layer 170 is disposed below the light-emitting element layer 120 and the pixel defining layer 130, and each light-emitting element 121 is separately controlled by providing an array of thin film transistors.

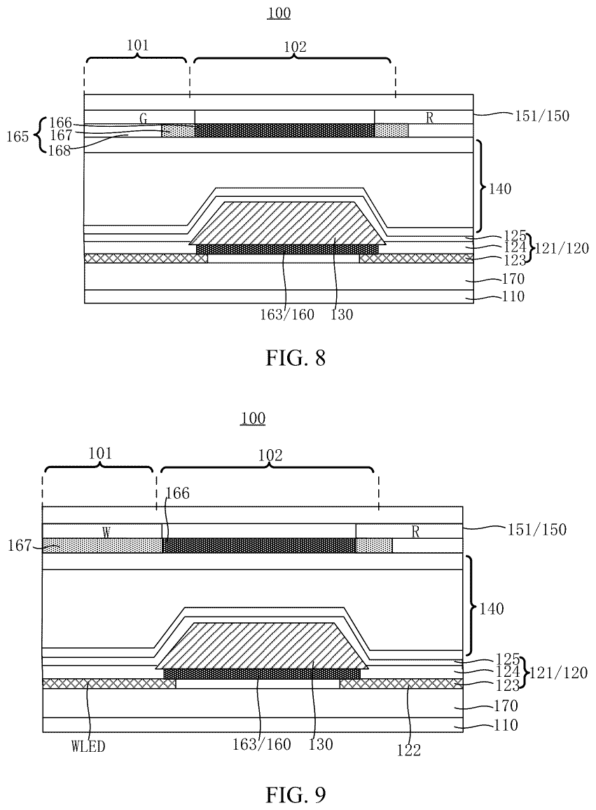

FIG. 8 is a schematic diagram of still another display panel ac-cording to a third embodiment of the present application. Referring to FIG. 8, specifically, the semi-shielding piece 167 is disposed between the light-shielding piece 166 and the light-transmitting piece 168, and the semi-shielding piece 167 extends from the opening region 101 to the non-opening region 102. The area of the semi-shielding piece 167 is less than the area of the light-shielding piece 166 and smaller than the area of the light-transmitting piece 168. In this embodiment, a transition region is achieved by setting the semi-shielding piece 167 between the light-shielding piece 166 and the light-transmitting piece 168. The semi-shielding piece 167 is annular and is arranged around the color filter 151 to reduce ambient light reflection mainly by filtering ambient light around the color filter 151. The area of the semi-shielding piece 167 does not exceed one quarter of the area of the corresponding color filter 151. In this embodiment, the light intensity around the color filter 151 is slightly reduced, but this brings about the effect of lower ambient light reflection of the color filter 151.

FIG. 9 is a schematic diagram of still another display panel ac-cording to the third embodiment of the present application. Referring to FIG. 9, in another specific embodiment, the plurality of light-emitting elements 121 include a plurality of white light-emitting elements WLED and a plurality of first light-emitting elements 122. An orthographic projection of the semi-shielding piece 167 on the substrate 110 overlaps an orthographic projection of the white light-emitting element WLED on the substrate 110. The plurality of color filters 151 are arranged in one-to-one correspondence with the plurality of first light-emitting elements 122. The plurality of first light-emitting elements 122 include at least two light-emitting elements 121 with different colors.

That is, the first light-emitting elements 122 include a first red light-emitting element 121, a first green light-emitting element 121, and a first blue light-emitting element 121. Each pixel includes at least a first red light-emitting element 121, a first green light-emitting element 121, a first blue light-emitting element 121, and a white light-emitting element WLED to form the RGBW display panel 100.

In a display panel 100 of the COE architecture, if it is an RGBW pixel architecture, the white sub-pixels tend to have more ambient light re-flection than the red, green and blue sub-pixels. In this application, by arranging the semi-shielding piece 167 on the white sub-pixel, although part of the emitted light of the white sub-pixel is lost and the brightness of the white sub-pixel is reduced, when the display panel 100 is in a dark state or some display area is in a dark state, most of the ambient light is filtered by the semi-shielding piece 167 and cannot enter the interior of the display panel 100 from the white sub-pixel area. This prevents ambient light from entering the interior of the display panel 100, being reflected single or multiple times by the various film layer, and emitting from the non-luminous display area, causing problems such as reflection and glare.

This embodiment is suitable for the RGBW display panel 100 and can mainly solve the reflection problem in the white sub-pixel area. It can be understood that the above-mentioned solution where the semi-shielding piece 167 is arranged around the color filter 151 and the solution where it is arranged in the white sub-pixel may be combined. Accordingly, on the one hand, the problem of ambient light reflection of the display panel 100 in the dark state is improved, and on the other hand, the display effect of the display panel 100 is improved.

### Embodiment 4

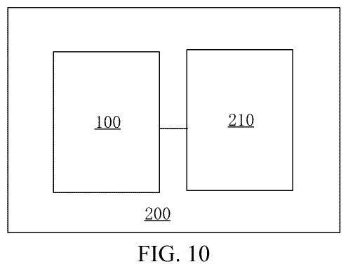

FIG. 10 is a schematic diagram of a display device according to a fourth embodiment of the present application. Referring to FIG. 10, this application discloses a display device. The display device 200 includes a driving circuit 210 and the display panel 100 described in any of the above embodiments. The driving circuit 210 is used to drive the display panel 100 to display.

This application uses the alignment film 161 and the polarizing molecules 162 disposed in the alignment film 161 to achieve the absorption of incident light from the outside by orienting the polarizing molecules 162, thus preventing external incident light from entering the display panel 100 which may cause some of the film layers in the display panel 100 to reflect the incident light hence leading to problems such as glare. In this application, the anti-reflection layer 160 is arranged corresponding to the pixel defining layer 130 so that the pixel defining layer 130 is shielded from light by the anti-reflection layer 160. Compared with the scheme of blackening the pixel defining layer 130 or disposing a black color filter on the pixel defining layer 130 for light-shielding, carbon black may be used to blacken the pixel defining layer 130, which causes the insulation of the pixel defining layer 130 to be weakened. If a black color filter is disposed on the pixel defining layer 130, the black color filter material will easily cause erosion and defects on the pixel defining layer 130. In this application, by arranging the alignment film 161 on the pixel defining layer 130, no interface characteristics may occur between the alignment film 161 and the pixel defining layer 130, and the manufacturing process of the alignment film 161 is mature. Thus, the anti-reflection layer 160 is used to improve the phenomenon of ambient light reflection without reducing the brightness and display effect. The anti-reflection layer 160 of the present application is formed by an alignment film 161 and polarizing molecules 162, and has a simple structure, simple manufacturing process, and low cost.

It should be noted that the inventive concept of the present application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing description is merely a further detailed description of the present application made with reference to some specific illustrative embodiments, and the specific implementations of the present application will not be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. A display panel, comprising an opening region and a non-opening region, wherein the display panel comprises:
a substrate;
a light-emitting element layer, comprising a plurality of light-emitting elements, which are arranged in an array on the substrate and located in the opening region;
a pixel defining layer, disposed on the substrate and located in the non-opening region; wherein every two adjacent light-emitting elements are separated by the pixel defining layer;
an encapsulation layer, arranged on the plurality of light-emitting elements and the pixel defining layer;
a color filter layer, comprising a plurality of color filters, which are arranged on the encapsulation layer and located in the opening region; and
an anti-reflection layer, arranged corresponding to the pixel defining layer and located in the non-opening region, and used for blocking external light from entering the display panel;
wherein the anti-reflection layer comprises an alignment film and a plurality of polarizing molecules that are evenly distributed in the alignment film; wherein the plurality of polarizing molecules are arranged in two mutually perpendicular orientations in the alignment film.

2. The display panel as recited in claim 1, wherein each of the plurality of light-emitting elements comprises a top electrode, a light-emitting layer, and a bottom electrode; wherein the bottom electrode, the light-emitting layer, and the top electrode are sequentially stacked on the substrate; wherein the bottom electrode is disposed under the pixel defining layer;
wherein the anti-reflection layer comprises a first anti-reflection layer that is disposed between the pixel defining layer and the bottom electrode.

3. The display panel as recited in claim 2, wherein an orthographic projection of the first anti-reflection layer on the substrate partially overlaps an orthographic projection of the bottom electrode on the substrate, resulting in a first overlapping width;
wherein an orthographic projection of the bottom electrode on the substrate partially overlaps an orthographic projection of the pixel defining layer on the substrate, resulting in a second overlapping width;
wherein the first overlapping width is less than or equal to the second overlapping width.

4. The display panel as recited in claim 1, wherein each of the plurality of light-emitting elements comprises a top electrode, a light-emitting layer, and a bottom electrode; wherein the bottom electrode, the light-emitting layer, and the top electrode are sequentially stacked on the substrate, and wherein the bottom electrode is disposed under the pixel defining layer;
wherein the anti-reflection layer comprises a second anti-reflection layer that is disposed between the pixel defining layer and the encapsulation layer.

5. The display panel as recited in claim 4, wherein there is defined a groove in the pixel defining layer, and wherein the second anti-reflection layer is disposed in the groove.

6. The display panel as recited in claim 4, wherein an orthographic projection of the second anti-reflection layer on the substrate partially overlaps an orthographic projection of the bottom electrode on the substrate.

7. The display panel as recited in claim 1, further comprising a local light-transmitting layer, wherein a part of the local light-transmitting layer is used to block the external light from entering the display panel, and wherein the local light-transmitting layer is disposed on the encapsulation layer;
wherein the local light-transmitting layer comprises a light-shielding piece and a light-transmitting piece, wherein the light-shielding piece is arranged corresponding to the non-opening region, and wherein the light-transmitting piece is arranged corresponding to the opening region;
wherein the plurality of polarizing molecules of the light-shielding piece are arranged in mutually perpendicular orientations in the alignment film, and wherein no polarizing molecules are disposed in the light-transmitting piece.

8. The display panel as recited in claim 7, wherein the local light-transmitting layer further comprises a semi-shielding piece, and wherein the plurality of polarizing molecules in the semi-shielding piece are arranged in a unidirectional orientation in the alignment film;
wherein the semi-shielding piece is disposed between the light-shielding piece and the light-transmitting piece, and wherein the semi-shielding piece extends from the opening region to the non-opening region;
wherein an area of the semi-shielding piece is smaller than an area of the light-shielding piece and smaller than an area of the light-transmitting piece.

9. The display panel as recited in claim 7, wherein the local light-transmitting layer further comprises a semi-shielding piece, and wherein the plurality of polarizing molecules of the semi-shielding piece are arranged in a unidirectional orientation in the alignment film;
wherein the plurality of light-emitting elements comprises a plurality of white light-emitting elements and a plurality of first light-emitting elements;
wherein an orthographic projection of the semi-shielding piece on the substrate overlaps an orthographic projection of the respective white light-emitting element on the substrate;
wherein the plurality of color filters are arranged in one-to-one correspondence with the plurality of first light-emitting elements; and
wherein the plurality of first light-emitting elements comprise at least two light-emitting elements with different colors.

10. The display panel as recited in claim 4, wherein an orthographic projection of the second anti-reflection layer on the substrate does not overlap an orthographic projection of the bottom electrode on the substrate.

11. The display panel of claim 6, wherein the second anti-reflection layer further covers both sides of the pixel defining layer, extends from one side of the pixel defining layer toward a top surface of the pixel defining layer, and further extends to and covers another side of the pixel defining layer.

12. The display panel as recited in claim 1, wherein each of the plurality of light-emitting elements comprises a top electrode, a light-emitting layer, and a bottom electrode; wherein the bottom electrode, the light-emitting layer, and the top electrode are sequentially stacked on the substrate, and wherein the bottom electrode is disposed under the pixel defining layer;
wherein the anti-reflection layer comprises a first anti-reflection layer and a second anti-reflection layer;
wherein the first anti-reflection layer is disposed between the pixel defining layer and the bottom electrode; and wherein the second anti-reflection layer is disposed between the pixel defining layer and the encapsulation layer.

13. The display panel as recited in claim 12, wherein there is defined a groove in the pixel defining layer, and wherein the second anti-reflection layer is disposed in the groove.

14. The display panel as recited in claim 8, wherein the semi-shielding piece has an annular shape and is arranged around the respective color filter.

15. The display panel as recited in claim 14, wherein an area of the semi-shielding piece does not exceed one quarter of an area of the corresponding color filter.

16. A display device, comprising a driving circuit and a display panel, wherein the driving circuit is used to drive the display panel to display; wherein the display panel comprises an opening region and a non-opening region; wherein the display panel comprises a substrate, a light-emitting element layer, a pixel defining layer, an encapsulation layer, a color filter layer, and an anti-reflection layer; wherein the light-emitting element layer comprises a plurality of light-emitting elements that are arranged in an array on the substrate and are located in the opening region; wherein the pixel defining layer is disposed on the substrate and located in the non-opening region, and wherein every two adjacent light-emitting elements are separated by the pixel defining layer; wherein the encapsulation layer is disposed on the plurality of light-emitting elements and the pixel defining layer; wherein the color filter layer comprises a plurality of color filters, which are disposed on the encapsulation layer and located in the opening region; wherein the anti-reflection layer is disposed corresponding to the pixel defining layer and is located in the non-opening region to block external light from entering the display panel; wherein the anti-reflection layer comprises an alignment film and a plurality of polarizing molecules that are evenly distributed in the alignment film, and wherein the plurality of polarizing molecules are mutually perpendicularly aligned in the alignment film.

17. The display device as recited in claim 16, wherein each of the plurality of light-emitting elements comprises a top electrode, a light-emitting layer, and a bottom electrode; wherein the bottom electrode, the light-emitting layer, and the top electrode are sequentially stacked on the substrate; and wherein the bottom electrode is disposed under the pixel defining layer;
wherein the anti-reflection layer comprises a first anti-reflection layer disposed between the pixel defining layer and the bottom electrode

18. The display device as recited in claim 17, wherein an orthographic projection of the first anti-reflection layer on the substrate partially overlaps an orthographic projection of the bottom electrode on the substrate, resulting in a first overlapping width;
wherein an orthographic projection of the bottom electrode on the substrate partially overlaps an orthographic projection of the pixel defining layer on the substrate, resulting in a second overlapping width;
wherein the first overlapping width is less than or equal to the second overlapping width.

19. The display panel as recited in claim 16, wherein each of the plurality of light-emitting elements comprises a top electrode, a light-emitting layer, and a bottom electrode; wherein the bottom electrode, the light-emitting layer, and the top electrode are sequentially stacked on the substrate, and wherein the bottom electrode is disposed under the pixel defining layer;
wherein the anti-reflection layer comprises a second anti-reflection layer that is disposed between the pixel defining layer and the encapsulation layer.
